(19) United States
(12) Patent Application Publication
(10) Pub. No.: US 2026/0186407 A1
(43) Pub. Date: Jul. 2, 2026

(54) BISMUTH BORONATE COMPOUNDS FOR EUV LITHOGRAPHY

(71) Applicant: Intel Corporation, Santa Clara, CA (US)

(72) Inventors: Scott SEMPRONI, Fair Lawn, NJ (US); Charles MOKHTARZADEH, Portland, OR (US)

(21) Appl. No.: 19/004,009

(22) Filed: Dec. 27, 2024

(51) Int. Cl. G03F 7/004; G03F 7/00; G03F 7/16; H01L 21/027

(52) U.S. Cl. CPC G03F 7/0042; G03F 7/167; G03F 7/70033; H10P 76/20

(57) ABSTRACT

Metal-oxide materials that are suitable for extreme ultraviolet lithography (EUV) applications are provided. Metal-oxide materials can comprise bismuth boronate oxide clusters and/or coordination compounds of various sizes. Methods of forming metal-oxide materials comprising bismuth and boron that are suitable for EUV semiconductor processing applications are also provided.

### FIELD

Descriptions are generally related to semiconductor device manufacturing, and more particular descriptions are related to boron-and bismuth-containing photoresists for lithography processes for semiconductor device manufacturing.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, limited failure tolerance, and material and manufacturing costs.

Lithographic processes are used in semiconductor manufacturing to create patterns for semiconductor device fabrication on wafers. A photo resist material layer and a mask can be used to pattern the surface of the wafer. Development of the photoresist leaves a pattern on the surface of the wafer through which, the developed (patterned) areas can be, for example, etched or deposited into, to create features for devices. Extreme ultraviolet radiation (EUV) can allow smaller features to be created through lithographic processes. In general, EUV lithography employes radiation that has a wavelength of 13.5 nm (although other values are possible). In order to fully take advantage of the small feature size possible with EUV lithography to manufacture new photoresists need to be developed.

### BRIEF DESCRIPTION OF THE DRAWINGS

The figures are provided to aid in understanding the disclosure. The figures can include diagrams and illustrations of examples of structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the disclosure. Additionally, features are not necessarily illustrated relatively to scale due in part to the small sizes of some features and the desire for clarity of explanation in the figures.

FIGS. 1A-1C provide methods for making metal-organic photoresists comprising bismuth and boron for lithography.

FIGS. 2A-2D show some exemplary boronic acids and esters useful for creating photoresists for lithographic processes.

FIG. 3 illustrates further methods for making metal-organic photoresists comprising bismuth and boron useful for lithographic processes.

FIG. 4 provides further additional methods for making metal-organic photoresists comprising bismuth, boron, carbon, and oxygen.

FIG. 5 also shows methods for making metal-organic photoresists comprising bismuth, boron, carbon, and oxygen.

FIG. 6 illustrates a process for semiconductor manufacturing that employs EUV lithography and a photoresist comprising bismuth and boron.

FIG. 7 provides an example of a computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, optically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine, as well as by physical operations. Physical operations can be performed by semiconductor processing equipment, including computer systems that operate aspects of semiconductor manufacturing tools and systems. Although shown in a particular sequence or order, unless otherwise specified, the order of the actions can be modified. Thus, the illustrated diagrams should be understood as examples. The processes can be performed in a different order, and some actions can be performed in parallel. Additionally, one or more actions can be omitted and not all implementations may necessarily perform all actions.

Various components described can be a means for performing the operations or functions described. Components described can include software, hardware, or a combination of these. Some components can be implemented as software modules, hardware modules, special-purpose hardware (for example, application specific hardware, application specific integrated circuits (ASICs), and digital signal processors (DSPs)), embedded controllers, and/or hardwired circuitry. Other components can be semiconductor processing equipment that is able to perform physical operations such as, for example, lithography, material deposition (for example, chemical vapor deposition, atomic layer deposition, physical vapor deposition, electrodeposition, and/or sputtering), chemical mechanical polishing, and etching.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, semiconductor device, and/or semiconductor chip are interchangeable and refer to a device comprising integrated circuits that can be formed in part from semiconductor materials.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Interconnects in, for example, semiconductor chips that are integrated into heterogeneous packages (such as, for example, packages that include memory and logic chips), can also include through silicon vias (TSVs) that transverse the semiconductor chip device region. Semiconductor devices that have TSVs can blur distinctions between BEOL and FEOL processes.

Semiconductor chip interconnects can be created by forming a trench or though-layer via by etching a trench or via structure into a dielectric layer and filling the trench or via with metal. Dielectric layers can comprise, for example, low-k dielectrics, SiO₂, silicon nitride (SIN), silicon carbide (SIC), and/or silicon carbonitride (SiCN). Low-k dielectrics include for example, fluorine-doped SiO₂, carbon-doped SiO₂, porous SiO₂, porous carbon-doped SiO₂, combinations for the foregoing, and also these materials with gas-filled gaps or bubbles.

Dielectric layers that include conducting features can be interlayer dielectric (ILD) features. In general, low-k dielectrics exhibit a dielectric constant that is less than that of SiO₂.

The terms “package,” “packaging,” “IC package,” or “chip package,” “microelectronics package,” or “semiconductor chip package” are interchangeable and generally refer to an enclosed carrier of one or more chips, in which the chips are coupled to a package substrate and encapsulated. The package substrate provides electrical interconnections between the chip(s) and other chips and/or a motherboard or other circuit board for I/O (input/output) communication and power delivery. A package with multiple chips can, for example, be a system in a package.

A package substrate generally includes dielectric layers or structures having conductive structures on, through, and/or embedded in the dielectric layers. The dielectric layers can be, for example, build-up layers. Dielectric materials include Ajinomoto build-up film (ABF), although other dielectric materials are possible. Semiconductor package substrates can have cores or be coreless. Semiconductor packages having cores can have dielectric layers such as buildup layers on more than one side of a core, such as on two opposite sides of a core.

Cores can include through-core vias that contain a conductive material. Other structures or devices are also possible within a package substrate.

Extreme Ultraviolet and High Numerical Aperture Extreme Ultraviolet (High NA EUV) lithographic patterning are enabling further reductions device feature size for semiconductor chips. Development of new photoresists that display increased efficiency with EUV photons as well as greater chemical stability can provide manufacturing and cost benefits.

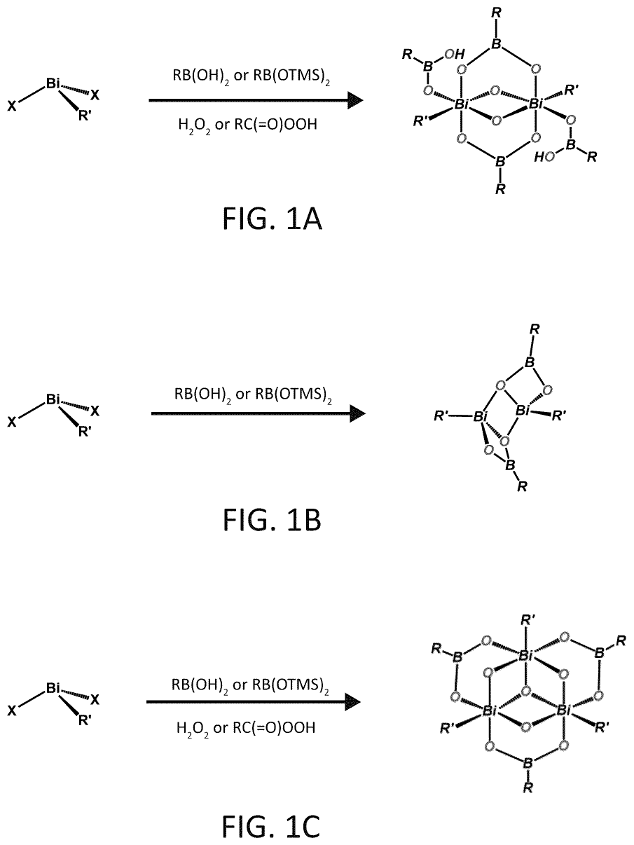

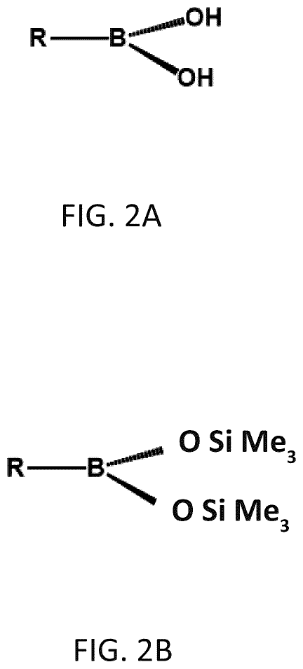

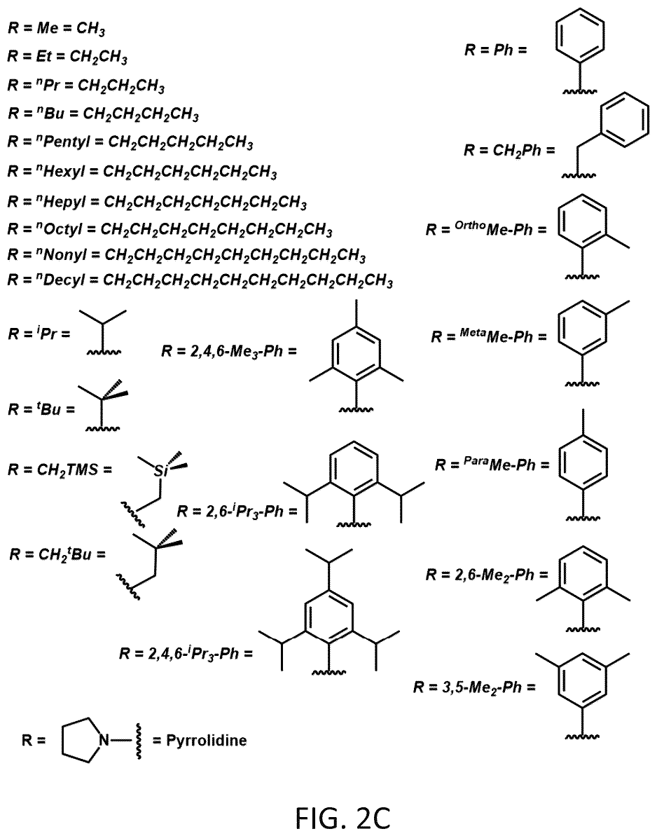

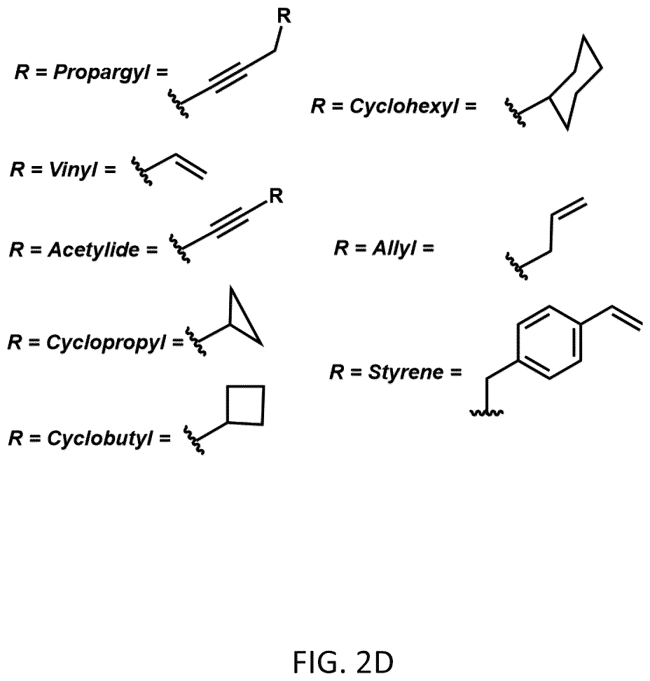

FIGS. 1A-1C illustrate processes for creating photoresists useful for lithographic processes, such as for example, EUV and/or High NA EUV lithographic processes for semiconductor manufacturing. A bismuth compound, R′BiX₂, can be reacted with a boronic acid (RB(OH)₂) or silyl boronate ester (RB(OTMS)₂ (TMS is a trimethylsilyl group —Si(CH₃)₃)) to create bismuth boronate oxycarbide clusters (or coordination polymers) of varying sizes. For the bismuth compound, R′ can be an alkyl group, for example, —CH₃ (methyl, —Me), —CH₂CH₃ (ethyl, —Et), —CH₂CH₂CH₃ (propyl, —Pr), butyl, 2-methyl butyl, tert-amyl, phenyl or substituted phenyl groups (aryl groups), alkyls that include vinyl, allylic, and propargyl groups, or any of the R groups shown in FIGS. 2C-2D . A reagent that is a mixture comprising two or more (or silyl boronate esters) that have different R groups is also possible. Similarly, a reagent that is a mixture comprising two or more bismuth compounds that have different R′ groups is also possible. X can be an acid labile group, for example, CI, Br, I, —OR (an alkoxide), where R can be any of the groups in FIG. 2C or 2D, —NR″₂, where R″ can be any of the groups in FIG. 2C or 2D, or a mixture of these groups. Bismuth boronate cluster morphology in a photoresist can be tuned by selecting the size of the substituent (R and/or R′ group) on bismuth and/or boron as well as through the inclusion or exclusion of additional oxidants in the reaction. The addition of an oxidant can control the bismuth oxidation state and thereby cluster size. Useful oxidants include, for example, H₂O₂, peroxy acids (R′″C(═O)OOH), NR′″₃—O, or R′″OOH (organic peroxides such as, for example, cumene hydroperoxide), where R″′ can be any of the groups in FIG. 2C or 2D.

In FIG. 1A, the inclusion of an oxidant (H₂O₂, RC(═O)OOH, or another oxidant, such as one described herein) can cause the formation of a larger sized bismuth boronate oxycarbide cluster having, for example, Bi(V) with a coordination number of 6. A smaller R and/or R′ group can lead to the formation of a larger cluster. In FIG. 1B, a larger R group and the exclusion of an oxidant can lead to a smaller sized bismuth boronate oxycarbide cluster having, for example, Bi(III) with a coordination number of 4. In FIG. 1C, the inclusion of an oxidant can be used to control bismuth oxidation state and thereby cluster size (e.g., a bismuth with six ligands). The inclusion of a larger R group can reduce the cluster size and can lead to the formation of an intermediate sized bismuth boronate oxycarbide cluster. Through adding organic substituents (on the boron) on the periphery of a bismuth boronate oxycarbide cluster, an aggregation mode between the clusters can be realized that further enables “crosslinking” upon EUV exposure. Crosslinking after EUV exposures can create negative tone photoresists.

FIGS. 2A-2D provide some exemplary boron compounds useful in the processes of FIGS. 1A-1C and 3-5. FIGS. 2A-2B show exemplary boron compounds: RB(OH)₂ in FIG. 2A and RB(OTMS)₂ in FIG. 2B. FIGS. 2C-2D provides some example R groups for the compounds of FIGS. 2A-2B that include, for example, alkyl groups, phenyl groups, pyrrolidine groups, cyclic alkanes (e.g., cyclopropyl, cyclobutyl, cyclohexyl), vinyl, allyl, propargyl, and groups comprising TMS. Other R groups are also possible since boronic acids can exhibit a high degree of functional group tolerance which allows them to be employed in complex reactions. The inclusion of boron in the bismuth boronate oxycarbide clusters can provide an additional handle for modularity (amount of cross-linking) so that cluster solubility and/or reactivity can be tuned. The boronic acids of FIG. 2A can be useful in the solution-phase synthesis of bismuth clusters for use in, for example, spin-on applications. The boronic acids of FIG. 2B can be synthesized through a reaction of the related boronic acid and trimethylsilylchloride. The boronic acids shown in FIG. 2B can serve as co-reactants in, for example, CVD or ALD photoresist formation processes with suitably selected bismuth precursors.

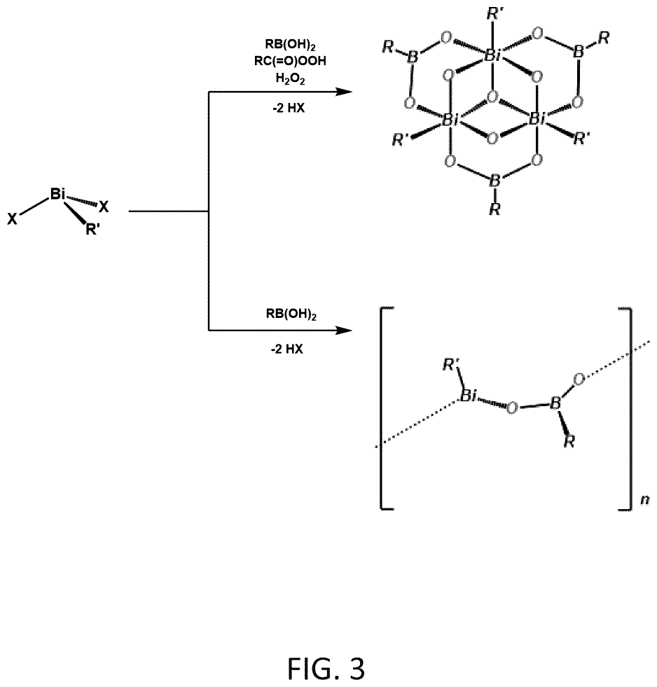

FIG. 3 provides further details for processes useful to form bismuth boronate oxycarbide clusters (or coordination polymers) of varying sizes on a semiconductor wafer. The reactions shown in FIG. 3 can be used for spin coating applications and a variety of cluster materials can be generated in accordance with the reactions shown in FIG. 3. A range of bismuth precursors can be used and the two acid labile groups, —X, can be protonated and thereby removed by the boronic acid reactant. The alkyl group, —R, are chosen to be resistant to hydrolysis by the boronic acid compound chosen as well as to impart desired characteristics to the bismuth boronate oxycarbide clusters (or coordination polymers) that are the reaction products. After product isolation, the bismuth boronate oxycarbide clusters (or coordination polymers) can be dissolved (or suspended) in a solvent for spin-coating applications.

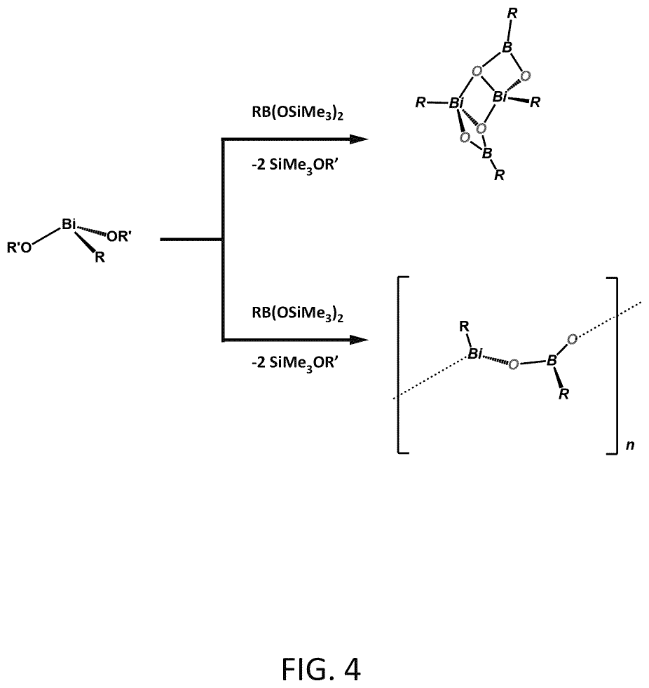

FIG. 4 shows methods for generating a photoresist films using heteroleptic bismuth precursors through either chemical vapor deposition or atomic layer deposition processes. The bismuth precursor is of the general formula RBi(OR′)₂ and the boronate compounds have the general formula RB(OSiMe₃)₂. The bismuth precursor and boron co-reagent can be co-flowed for a CVD process or the bismuth precursor and boron co-reagent can be sequentially pulsed for an ALD process. Cluster size can be modified through the addition of an oxidant and/or the choice of —R groups.

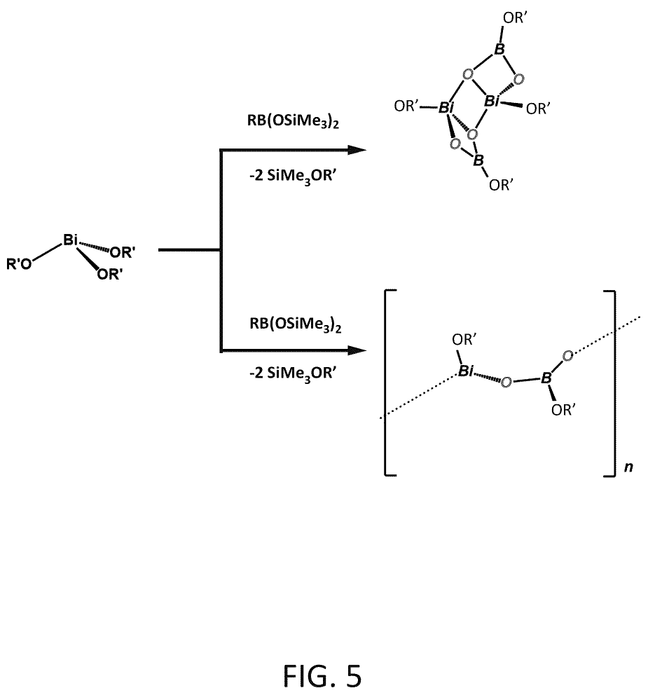

FIG. 5 shows methods for generating photoresist films using homoleptic bismuth precursors through either chemical vapor deposition or atomic layer deposition processes. The bismuth precursor is of the general formula Bi(OR′)₃ and the boronate compounds have the general formula RB(OSiMe₃)₂. The bismuth precursor and boron co-reagent can be co-flowed for a CVD process and the bismuth precursor and boron co-reagent can be sequentially pulsed for an ALD process. Cluster size can be modified through the addition of an oxidant and/or the choice of-R groups.

In FIGS. 3-5 , R and R′ can be, for example, any of the groups shown in FIGS. 2C-2D , and X can be, CI, Br, I, —OR (an alkoxide), where R can be any of the groups in FIG. 2C or 2D, —NR″₂, where R″ can be any of the groups in FIG. 2C or 2D, or a mixture of these groups.

Bismuth boronate oxycarbide clusters can also be coordination polymers.

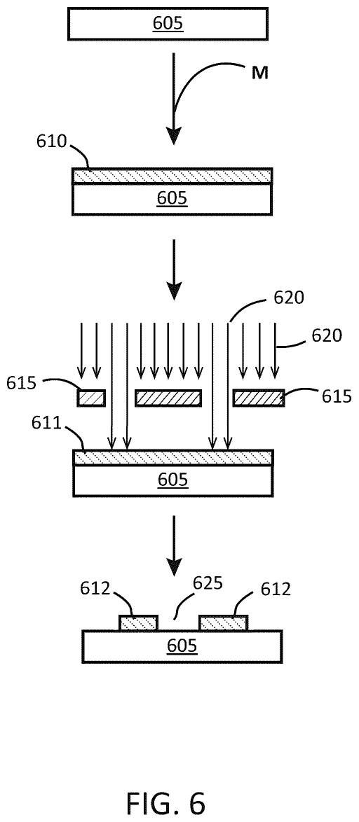

FIG. 6 illustrates a process for creating a bismuth boronate oxycarbide photoresist film 610 that is useful for lithographic processes, on a semiconductor device substrate 605. The bismuth boronate oxycarbide photoresist film can comprise, for example, clusters or coordination polymers. M can be reagents that are in the vapor (or gas) phase, in the case of a CVD or ALD process in which reagents are supplied to a chamber, or bismuth boronate oxycarbide compounds can be in a solution for a spin-on process. The spin-on solution can comprise a solvent such as, for example, propylene glycol monomethyl ether acetate (PGMEA), 1-methoxy-2-propanol (PGME), ethyl lactate, propylene carbonate, 2-heptanone, cyclohexanone, toluene, octane, tetrahydrofuran (THF), anisole, dioxane, 1-butanol, 4-methyl-2-pentanone. The solvent in the spin-on solution can be evaporated after a spin coating process, leaving a bismuth boronate oxycarbide film 610. The precursors and/or bismuth boronate oxycarbide compounds can be any of those described herein and shown with respect to FIGS. 1A-1C, 2A-2C , and 3-5. A lithographic process can employ EUV radiation 620 and a lithographic mask 615 that partially blocks incoming radiation from reaching the entire surface of the photoresist film 610. EUV radiation can cause additional crosslinking in the bismuth boronate oxycarbide photoresist that decreases the solubility of the bismuth boronate oxycarbide photoresist in the irradiated portions. The modified photoresist film 611 can be developed by dissolving away the portions of the photoresist 610 that have not been irradiated. The resulting gaps 625 in the photoresist film 612 can be used, for example, to selectively etch the surface of the semiconductor device substrate 605 or to deposit a material to create a feature in and defined by a gap 625. After further manufacturing processes (e.g., etching or deposition), the photoresist 612 can be removed with a stronger solvent than was first used to dissolve portions of the photoresist film 611.

In some examples, bismuth boronate oxycarbide photoresist films as described here can exhibit the relative ratios of Bi:O:B of between 1:2:1 and 2:10:4 or between 1:2:1 and 3:10:3.

Semiconductor device substrates can be, for example, a silicon or silicon-on-insulator substate. Other materials for semiconductor substrates include, gallium arsenide, germanium, indium antimonide, lead telluride, indium phosphide, indium antimonide, indium gallium arsenide, or gallium antimonide. Other types of substrates are also possible and the devices described herein are not limited to a particular type of substrate.

A computer-readable medium on which instructions are stored in a non-transitory form, that when executed by a computer, can cause a system to perform any of the methods described herein and illustrated in the accompanying figures.

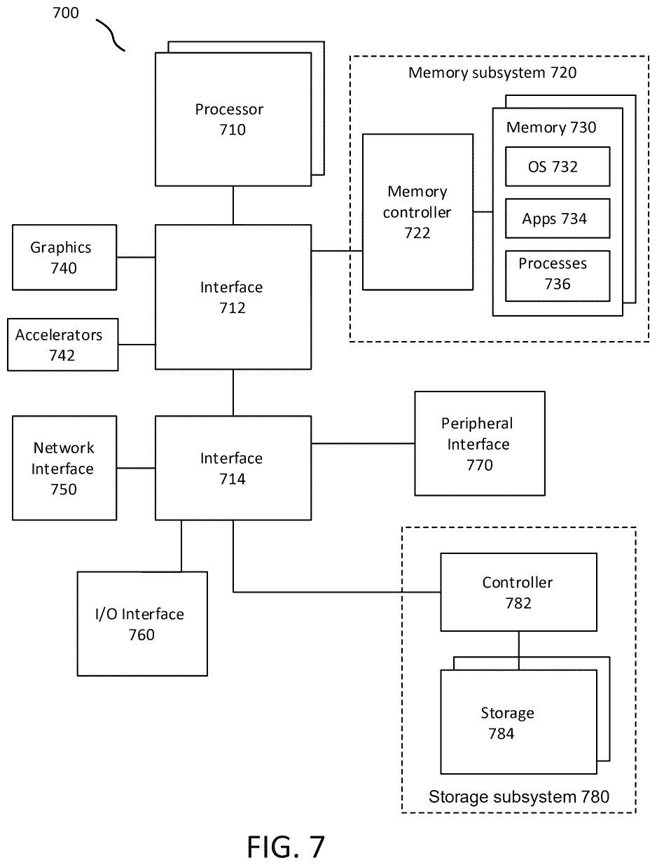

FIG. 7 depicts an example computing system. The computing system can be a system used for running equipment in a semiconductor fabrication plant. For example, instructions for performing one or more aspects of the process described herein can be stored and/or run on the computing system. A computing system 700 can include more, different, or fewer features than the ones described with respect to FIG. 7.

Computing system 700 includes processor 710, which provides processing, operation management, and execution of instructions for system 700. Processor 710 can include any type of microprocessor, CPU (central processing unit), GPU (graphics processing unit), processing core, or other processing hardware to provide processing for system 700, or a combination of processors or processing cores. Processor 710 controls the overall operation of system 700, and can be or include, one or more programmable general-purpose or special-purpose microprocessors, DSPs, programmable controllers, ASICs, programmable logic devices (PLDs), or the like, or a combination of such devices.

In one example, system 700 includes interface 712 coupled to processor 710, which can represent a higher speed interface or a high throughput interface for system components needing higher bandwidth connections, such as memory subsystem 720 or graphics interface components 740, and/or accelerators 742. Interface 712 represents an interface circuit, which can be a standalone component or integrated onto a processor die. Where present, graphics interface 740 interfaces to graphics components for providing a visual display to a user of system 700. In one example, the display can include a touchscreen display.

Accelerators 742 can be a fixed function or programmable offload engine that can be accessed or used by a processor 710. For example, an accelerator among accelerators 742 can provide data compression (DC) capability, cryptography services such as public key encryption (PKE), cipher, hash/authentication capabilities, decryption, or other capabilities or services. In some cases, accelerators 742 can be integrated into a CPU socket (e.g., a connector to a motherboard (or circuit board, printed circuit board, mainboard, system board, or logic board) that includes a CPU and provides an electrical interface with the CPU). For example, accelerators 742 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 742 can provide multiple neural networks, CPUs, processor cores, general purpose graphics processing units, or graphics processing units can be made available for use by artificial intelligence (Al) or machine learning (ML) models.

Memory subsystem 720 represents the main memory of system 700 and provides storage for code to be executed by processor 710, or data values to be used in executing a routine. Memory subsystem 720 can include one or more memory devices 730 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 730 stores and hosts, among other things, operating system (OS) 732 that provides a software platform for execution of instructions in system 700, and stores and hosts applications 734 and processes 736. In one example, memory subsystem 720 includes memory controller 722, which is a memory controller to generate and issue commands to memory 730. The memory controller 722 can be a physical part of processor 710 or a physical part of interface 712. For example, memory controller 722 can be an integrated memory controller, integrated onto a circuit within processor 710.

System 700 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCle) bus, a Hyper Transport or industry standard architecture (ISA) bus, a small computer system interface (SCSI) bus, a universal serial bus (USB), or a Firewire bus.

In one example, system 700 includes interface 714, which can be coupled to interface 712. In one example, interface 714 represents an interface circuit, which can include standalone components and integrated circuitry. In one example, user interface components or peripheral components, or both, couple to interface 714. Network interface 750 provides system 700 the ability to communicate with remote devices (e.g., servers or other computing devices) over one or more networks. Network interface 750 can include an Ethernet adapter, wireless interconnection components, cellular network interconnection components, USB, or other wired or wireless standards-based or proprietary interfaces. Network interface 750 can transmit data to a device that is in the same data center or rack or a remote device, which can include sending data stored in memory.

Some examples of network interface 750 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 700 includes one or more input/output (I/O) interface(s) 760. I/O interface 760 can include one or more interface components through which a user interacts with system 700 (e.g., audio, alphanumeric, tactile/touch, or other interfacing).

Peripheral interface 770 can include additional types of hardware interfaces, such as, for example, interfaces to semiconductor fabrication equipment and/or electrostatic charge management devices.

In one example, system 700 includes storage subsystem 780. Storage subsystem 780 includes storage device(s) 784, which can be or include any conventional medium for storing data in a nonvolatile manner, such as one or more magnetic, solid state, and/or optical based disks. Storage 784 can be generically considered to be a “memory,” although memory 730 is typically the executing or operating memory to provide instructions to processor 710.

Whereas storage 784 is nonvolatile, memory 730 can include volatile memory (e.g., the value or state of the data is indeterminate if power is interrupted to system 700). In one example, storage subsystem 780 includes controller 782 to interface with storage 784. In one example controller 782 is a physical part of interface 712 or processor 710 or can include circuits or logic in both processor 710 and interface 714.

A power source (not depicted) provides power to the components of system 700. More specifically, power source typically interfaces to one or multiple power supplies in system 700 to provide power to the components of system 700.

Examples of systems may be implemented in various types of computing, smart phones, tablets, personal computers, and networking equipment, such as switches, routers, racks, and blade servers such as those employed in a data center and/or server farm environment.

### EXAMPLES

A method can comprise: supplying first compound comprising bismuth and a second compound comprising boron to a chamber wherein the chamber includes a semiconductor substrate; allowing the first and second compounds to react; and depositing a film on the semiconductor substrate wherein the film comprises a reaction product of the first and the second compound and wherein the film comprises Bi, O, C, and B. The first and the second compounds can be introduced to the chamber in a gas phase. The film can comprise a material having relative ratios of Bi:O:B of between 1:2:1 and 3:10:3. The second compound comprising boron can have a formula RB(OSiMe₃)₂, wherein R comprises an alkyl group or a phenyl group. The second compound comprising boron can have a formula RB(OSiMe₃)₂ wherein R comprises a pyrrolidine group or a trimethylsilane group. The first compound comprising bismuth can have a formula RBi(OR′)₂ wherein R comprises an alkyl group or a phenyl group and wherein R′ comprises an alkyl group or a phenyl group. The first compound comprising bismuth can have a formula Bi(OR)₃ wherein R comprises an alkyl group or a phenyl group. The method can also include supplying a third compound comprising a peroxide or a peroxy acid. The method can also include exposing at least a portion of the film to extreme ultraviolet radiation. The semiconductor substrate can comprise silicon, silicon dioxide, gallium arsenide, germanium, indium antimonide, lead telluride, indium phosphide, indium antimonide, indium gallium arsenide, or gallium antimonide.

A method can comprise: supplying a solution comprising a solvent and a compound comprising Bi, B, O, and C, to a surface of a substrate; forming a layer of the solution on the surface of the substrate; and forming a film on the surface of the substrate wherein the film comprises a material having relative ratios of Bi:O:B of between 1:2:1 and 3:10:3. Forming the film can include evaporating solvent from the layer of solution. The compound can comprise an alkyl or an aryl group. The film can comprise an alkyl or an aryl group. The film can comprise Bi having a coordination number of 6. The film can comprise Bi having a coordination number of 4. The method can also include exposing at least a portion of the film to extreme ultraviolet radiation. The substrate can comprise silicon, silicon dioxide, gallium arsenide, germanium, indium antimonide, lead telluride, indium phosphide, indium antimonide, indium gallium arsenide, or gallium antimonide.

A solution can comprise: a solvent; and a compound having relative ratios of Bi:O:B between 1:2:1 and 3:10:3, wherein the compound additionally comprises an alkyl or an aryl group. The solvent can be propylene glycol monomethyl ether acetate (PGMEA), 1-methoxy-2-propanol (PGME), ethyl lactate, propylene carbonate, 2-heptanone, cyclohexanone, toluene, octane, tetrahydrofuran (THF), anisole, dioxane, 1-butanol, 4-methyl-2-pentanone.

Besides what is described herein, various modifications can be made to what is disclosed and implementations without departing from their scope. Therefore, the illustrations and examples herein should be construed in an illustrative, and not a restrictive sense.

1. A method comprising:
supplying first compound comprising bismuth and a second compound comprising boron to a chamber wherein the chamber includes a semiconductor substrate;
allowing the first and second compounds to react; and
depositing a film on the semiconductor substrate wherein the film comprises a reaction product of the first and the second compound and wherein the film comprises Bi, O, C, and B.

2. The method of claim 1 wherein the first and the second compounds are introduced to the chamber in a gas phase.

3. The method of claim 1 wherein the film comprises a material having relative ratios of Bi:O:B of between 1:2:1 and 3:10:3.

4. The method of claim 1 wherein the second compound comprising boron has a formula RB(OSiMe₃)₂, wherein R comprises an alkyl group or a phenyl group.

5. The method of claim 1 wherein the second compound comprising boron has a formula RB(OSiMe₃)₂ wherein R comprises a pyrrolidine group or a trimethylsilane group.

6. The method of claim 1 wherein the first compound comprising bismuth has a formula RBi(OR′)₂ wherein R comprises an alkyl group or a phenyl group and wherein R′ comprises an alkyl group or a phenyl group.

7. The method of claim 1 wherein the first compound comprising bismuth has a formula Bi(OR)₃ wherein R comprises an alkyl group or a phenyl group.

8. The method of claim 1 also including supplying a third compound comprising a peroxide or a peroxy acid.

9. The method of claim 1 also including exposing at least a portion of the film to extreme ultraviolet radiation.

10. The method of claim 1 wherein the semiconductor substrate comprises silicon, silicon dioxide, gallium arsenide, germanium, indium antimonide, lead telluride, indium phosphide, indium antimonide, indium gallium arsenide, or gallium antimonide.

11. A method comprising:
supplying a solution comprising a solvent and a compound comprising Bi, B, O, and C, to a surface of a substrate;
forming a layer of the solution on the surface of the substrate; and
forming a film on the surface of the substrate wherein the film comprises a material having relative ratios of Bi:O:B of between 1:2:1 and 3:10:3.

12. The method of claim 11 wherein forming the film includes evaporating solvent from the layer of solution.

13. The method of claim 11 wherein the compound comprises an alkyl or an aryl group.

14. The method of claim 11 wherein the film comprises an alkyl or an aryl group.

15. The method of claim 11 wherein the film comprises Bi having a coordination number of 6.

16. The method of claim 11 wherein the film comprises Bi having a coordination number of 4.

17. The method of claim 11 also including exposing at least a portion of the film to extreme ultraviolet radiation.

18. The method of claim 11 wherein the substrate comprises silicon, silicon dioxide, gallium arsenide, germanium, indium antimonide, lead telluride, indium phosphide, indium antimonide, indium gallium arsenide, or gallium antimonide.

19. A solution comprising:
a solvent; and
a compound having relative ratios of Bi:O:B between 1:2:1 and 3:10:3, wherein the compound additionally comprises an alkyl or an aryl group.

20. The solution of claim 19 wherein the solvent is propylene glycol monomethyl ether acetate (PGMEA), 1-methoxy-2-propanol (PGME), ethyl lactate, propylene carbonate, 2-heptanone, cyclohexanone, toluene, octane, tetrahydrofuran (THF), anisole, dioxane, 1-butanol, or 4-methyl-2-pentanone.
